(19) United States
(12) Patent Application Publication
(10) Pub. No.: US 2025/0328705 A1
(43) Pub. Date: Oct. 23, 2025

(54) MANAGEMENT OF SYSTEM HEALTH BY CUSTOMER-DEFINED SERVICE LEVEL AGREEMENTS AND SERVICE LEVEL OBJECTIVES

(71) Applicant: Dell Products L.P., Round Rock, TX (US)

(72) Inventors: Ofir Ezrielev, Sheva (IL); Liran Pekel, Gilat (IL); Rivka Yaackobi, Sheva (IL)

(21) Appl. No.: 18/638,050

(22) Filed: Apr. 17, 2024

(51) Int. Cl. G06F 30/20

(52) U.S. Cl. CPC G06F 30/20

(57) ABSTRACT

A method for managing system of a production environment includes obtaining, from a client device, a request for remediation of a user-defined parameter of the production environment, determining a set of potential remediation actions for the user-defined parameter, applying each of the set of potential remediation actions to a simulated production environment to obtain a set of remediation results, updating a system health display using the set of remediation results to obtain an updated system health display, wherein the updated system health display comprises a display of the user-defined parameter and an impact of a remediation action of the set of remediation actions on the user-defined parameter, and implementing the remediation action of the set of remediation actions to service the request for remediation.

### BACKGROUND

The management of system health of a production environment may be beneficial to a customer utilizing the production environment to aid in maintaining previously-set objectives. A user of the production environment may benefit from understanding the relationship between the current system health and the previously-set objectives. Further, the user may benefit from understanding how to remediate when the current system health is not up to par with these objectives.

### BRIEF DESCRIPTION OF DRAWINGS

Certain embodiments of the invention will be described with reference to the accompanying drawings. However, the accompanying drawings illustrate only certain aspects or implementations of the invention by way of example and are not meant to limit the scope of the claims.

FIG. 1.1 shows a diagram of a system in accordance with one or more embodiments of the invention.

FIG. 1.2 shows a diagram of a system health manager in accordance with one or more embodiments of the invention.

FIG. 2.1 shows a flowchart of a method of generating a system health display in accordance with one or more embodiments of the invention.

FIG. 2.2 shows a flowchart of a method of updating the system health display using a replicated or simulated environment in accordance with one or more embodiments of the invention.

FIGS. 3.1-3.4 show an example in accordance with one or more embodiments of the invention.

FIG. 4 shows a diagram of a computing device in accordance with one or more embodiments of the invention.

### DETAILED DESCRIPTION

Specific embodiments of the invention will now be described in detail with reference to the accompanying figures. In the following detailed description of the embodiments of the invention, numerous specific details are set forth in order to provide a more thorough understanding of one or more embodiments of the invention. However, it will be apparent to one of ordinary skill in the art that one or more embodiments of the invention may be practiced without these specific details. In other instances, well-known features have not been described in detail to avoid unnecessarily complicating the description.

In the following description of the figures, any component described with regard to a figure, in various embodiments of the invention, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments of the invention, any description of the components of a figure is to be interpreted as an optional embodiment, which may be implemented in addition to, in conjunction with, or in place of the embodiments described with regard to a corresponding like-named component in any other figure.

Throughout this application, elements of figures may be labeled as A to N. As used herein, the aforementioned labeling means that the element may include any number of items, and does not require that the element include the same number of elements as any other item labeled as A to N. For example, a data structure may include a first element labeled as A and a second element labeled as N. This labeling convention means that the data structure may include any number of the elements. A second data structure, also labeled as A to N, may also include any number of elements. The number of elements of the first data structure, and the number of elements of the second data structure, may be the same or different.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or preceded) the second element in an ordering of elements.

As used herein, the phrase operatively connected, or operative connection, means that there exists between elements/components/devices a direct or indirect connection that allows the elements to interact with one another in some way. For example, the phrase ‘operatively connected’ may refer to any direct connection (e.g., wired directly between two devices or components) or indirect connection (e.g., wired and/or wireless connections between any number of devices or components connecting the operatively connected devices). Thus, any path through which information may travel may be considered an operative connection.

In general, embodiments disclosed herein include methods and systems for managing the system health of a production environment. Specifically, embodiments disclosed herein include utilizing a system health management component that generates a system health dashboard associated with the operations of the production environment. The system health dashboard may be based on a monitoring of system resources, execution of workloads, and/or other parameters of the production environment. Further, the system health display may generate indicators corresponding to user-defined parameters for a system parameter and a relationship between the monitored operation and the user-defined parameters. While the discussion of the system health uses a system health display, the display may be interactive to a user accessing the display. In this manner, the display may be updated or modified in accordance with the interaction. For example, the display may be implemented as a graphical user interface (GUI).

For any operations that are detected to be outside the constraints of the user-defined parameters, or for any of the operations disclosed herein, a system health manager may further initiate a set of remediation actions on a simulated or replicated environment intended to replicate (or simulate) the production environment and its response to the remediation actions. The reaction of the replicated (or simulated) environment may be displayed in the system health display. A user of the production host environment may further view an estimated impact of each of the set of remediation actions on the operations of the production environment and determine, based on the displayed information, a remediation action to be performed on the production environment. Embodiments disclosed herein may further include implementing any selected remediation actions on the production environment.

The following describes various embodiments of the invention.

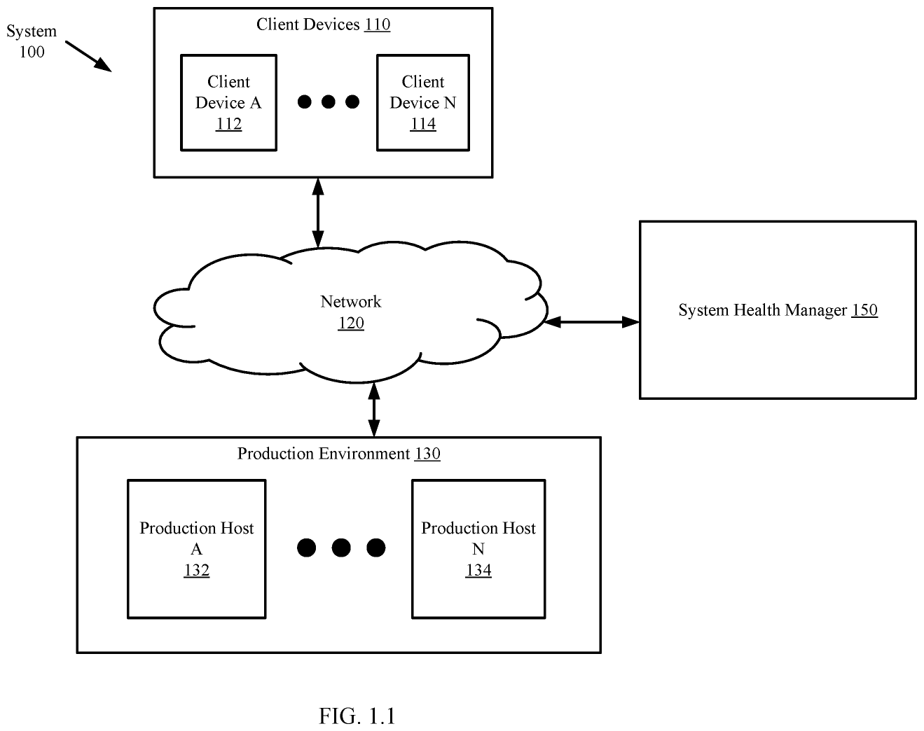

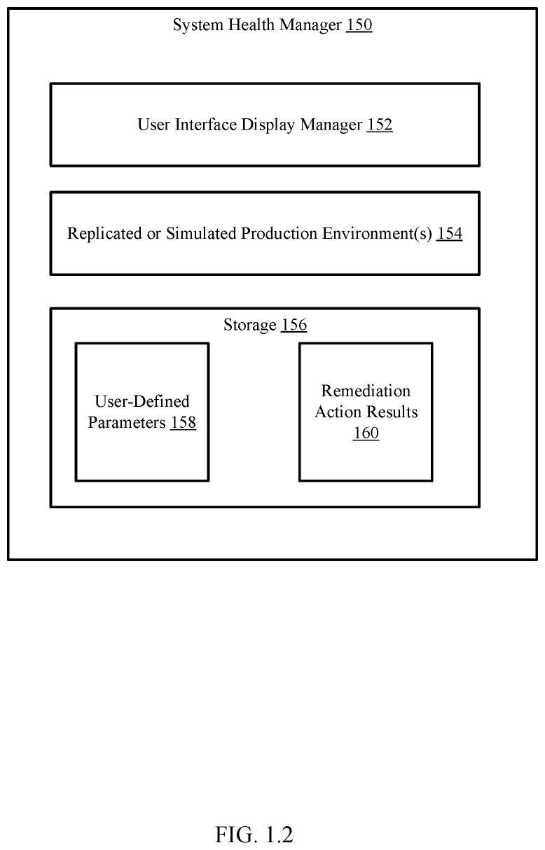

FIG. 1 shows a system in accordance with one or more embodiments of the invention. The system (100) includes any number of client devices (110), a network (120), a production environment (130), and a system health manager (150). The system (100) may include additional, fewer, and/or different components without departing from scope of the invention. Each component may be operably connected to any of the other component via any combination of wired and/or wireless connections. Each component illustrated in FIG. 1 is discussed below.

In one or more embodiments of the invention, the production environment (130) includes any number of production hosts (132, 134) that may each include functionality to provide computer-implemented services to users. The computer-implemented services may include, for example, instances of applications, virtual machines, instances of databases, data storage, data processing, cyber-security operations, and/or any other services without departing from the invention.

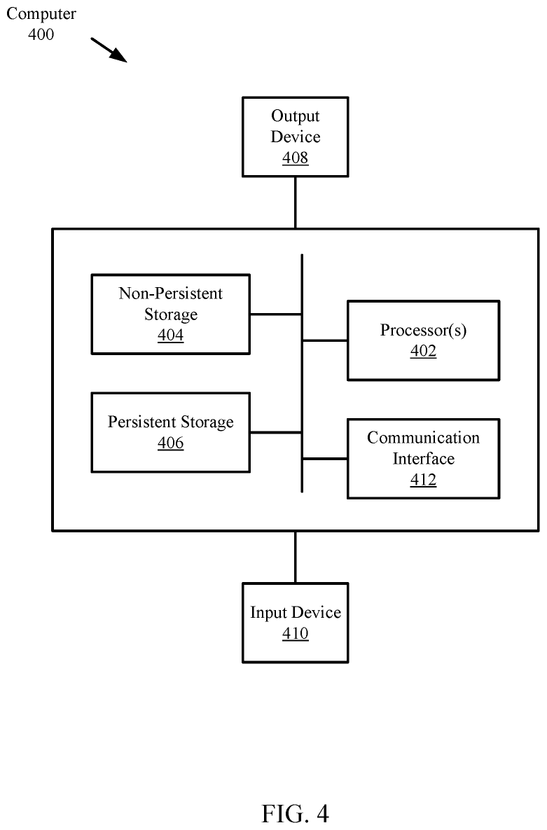

In one or more embodiments of the invention, each production host (132, 134) may be implemented as a computing devices (e.g., 400, FIG. 4). A computing device may be, for example, a mobile phone, a tablet computer, a laptop computer, a desktop computer, a server, a distributed computing system, or a cloud resource. The computing device may include one or more processors, memory (e.g., RAM), and persistent storage (e.g., disk drives, SSDs, etc.). The computing device may include instructions, stored on the persistent storage, that when executed by the processor(s) of the computing device cause the computing device to perform the functionality of the production host (132, 134) (and/or any components illustrated within) described throughout this present disclosure.

Alternatively, in one or more embodiments of the invention, the production environment (130) (and/or any components illustrated within) may be implemented as logical devices. A logical device may utilize the computing resources of any number of computing devices to provide the functionality of the production environment (130) (and/or any components illustrated within) described throughout this present disclosure.

In one or more embodiments of the invention, the above-mentioned system (100) components may operatively connect to one another through a network (120) (e.g., a local area network (LAN), a wide area network (WAN), a mobile network, a wireless LAN (WLAN), etc.). In one or more embodiments, the network (120) may be implemented using any combination of wired and/or wireless connections. The network (120) may encompass various interconnected, network-enabled subcomponents (not shown) (e.g., switches, routers, gateways, etc.) that may facilitate communications between the above-mentioned system (100) components.

In one or more embodiments of the invention, the network-enabled subcomponents may be capable of: (i) performing one or more communication schemes (e.g., Internet protocol communications, Ethernet communications, communications via any security protocols, etc.); (ii) being configured by the computing devices in the network (120); and (iii) limiting communication(s) on a granular level (e.g., on a per-port level, on a per-sending device level, etc.).

In one or more embodiments, the system health manager (150) includes functionality for managing the system health of the production environment (130). Specifically, the system health manager (150) monitors the resource use and performance metrics of the resources in the production environment (130). The system health manager (150) may further include functionality for generating system health displays based on a system health dashboard generated from the monitoring. The system health dashboard may specify the results of the performance, resource use, and/or other factors of the production environment. The system health display may be a graphical user interface representation of the system health dashboard.

In one or more embodiments, the system health displays of the production environments specify parameters of the production environment as a relationship to user-defined parameters. For example, a parameter that is displayed may include a performance parameter (e.g., a performance of the production hosts (132, 134)) when performing a workload. Additional parameters may include, for example, a latency parameter, an energy consumption parameter, a storage capacity parameter, and a workload capacity parameter. Other parameters may be illustrated in the system health display without departing from the invention.

In one or more embodiments, the parameters illustrated in the system health displays are indicators that are related to the user-defined parameters. The user-defined parameters may include, for example, service-level agreements (SLAs) and service-level objectives (SLOs). In one or more embodiments, the SLAs refer to expected metrics agreed by the provider of the production environment (130) (e.g., a corporate entity that owns the production hosts (132, 134) and provides its services) and the users of the client devices (110). The SLAs may be indicated as numerical values that represent the expected metrics. The expected metrics may be minimum values for given parameters that may be expected to be met by the production environment. The SLAs may be defined by an administrator of the client devices (110). In one or more embodiments, the SLOs relate to preferred values of the corresponding parameters.

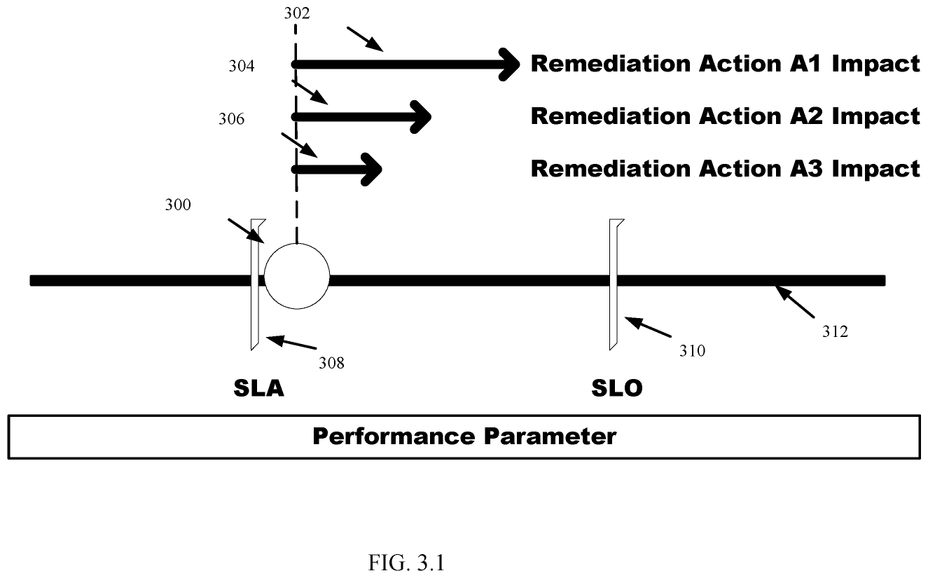

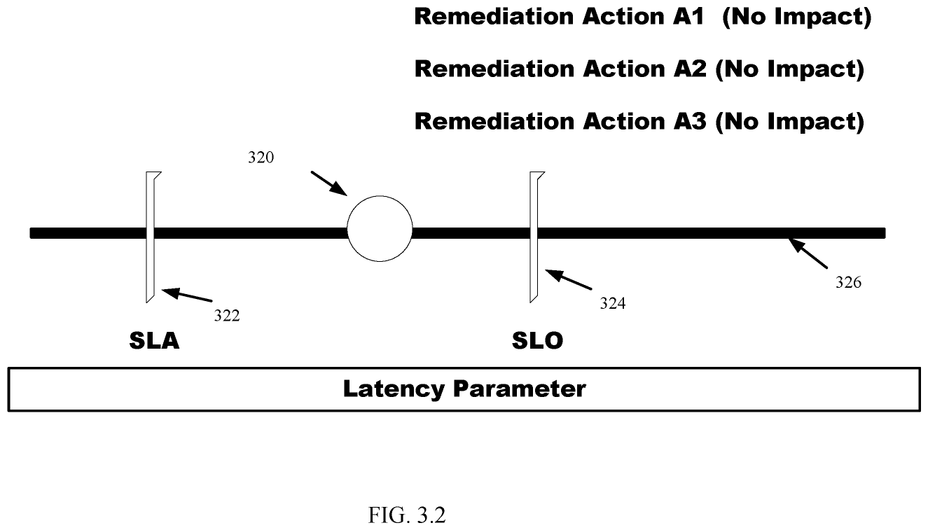

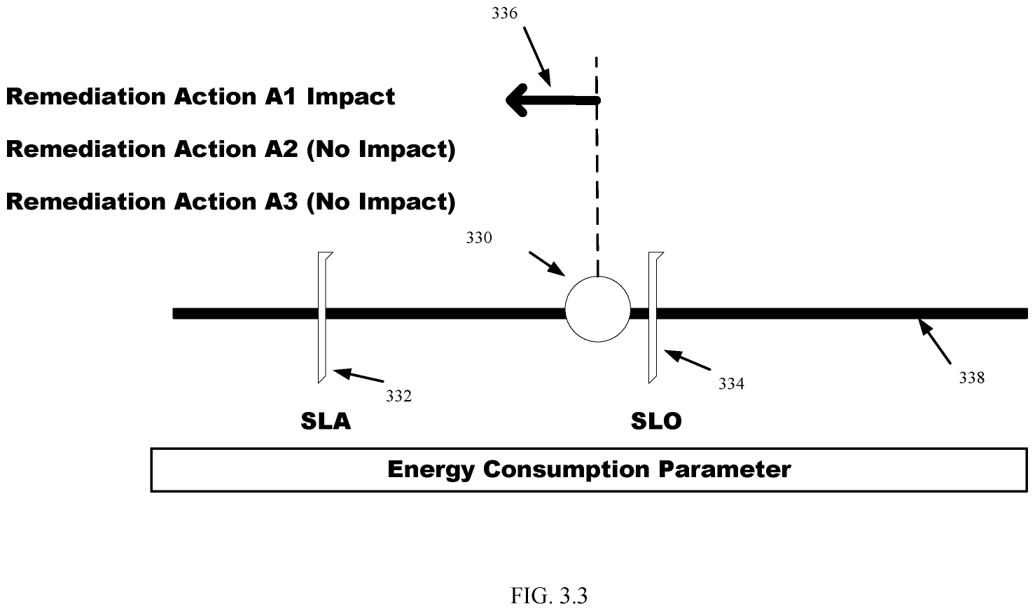

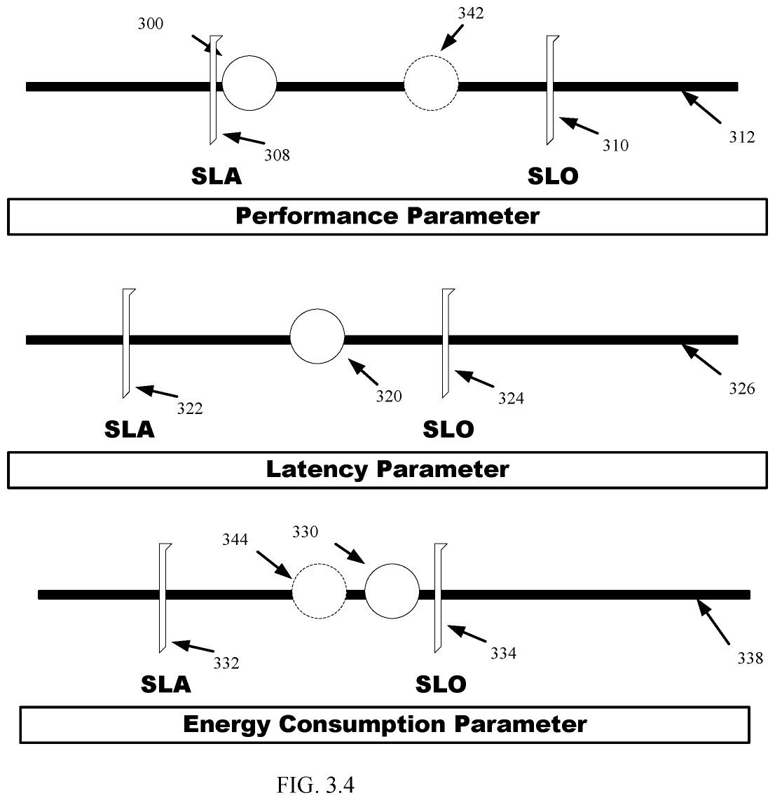

For example, a latency SLA may specify a maximum latency of 100 milliseconds (ms) of network transmission time. The SLOs may specify a preferred latency of 5 ms. The system health display may specify the current measured latency between the production environment (130) and one of the client devices (112, 114) for data transmission of a given workload. The current measured latency may be illustrated relative to the SLAs and the SLOs of this example. For additional details regarding an example system health display, refer to FIGS. 3.1-3.4.

In one or more embodiments of the invention, the system health manager (150) is implemented as a computing devices (e.g., 400, FIG. 4). A computing device may be, for example, a mobile phone, a tablet computer, a laptop computer, a desktop computer, a server, a distributed computing system, or a cloud resource. The computing device may include one or more processors, memory (e.g., RAM), and persistent storage (e.g., disk drives, SSDs, etc.). The computing device may include instructions, stored on the persistent storage, that when executed by the processor(s) of the computing device cause the computing device to perform the functionality of the system health manager (150) described throughout this present disclosure.

Alternatively, in one or more embodiments of the invention, the system health manager (150) is implemented as a logical device. A logical device may utilize the computing resources of any number of computing devices to provide the functionality of the system health manager (150) described throughout this present disclosure. For additional details regarding the system health manager, refer to FIG. 1.2.

FIG. 1.2 shows a diagram of the system health manager. The system health manager (150) may include a user interface display manager (152), one or more replicated or simulated environments (154), and storage (156). The system health manager (150) may include additional, fewer, and/or different components without departing from the invention.

In one or more embodiments, the user interface display manager (152) includes functionality for generating system health displays based on a system health dashboard implemented by the system health manager (150) and using user-defined parameters (158). As discussed above, the system health displays may indicate current indicators of the production environment relative to user-defined parameters such as SLOs and SLAs.

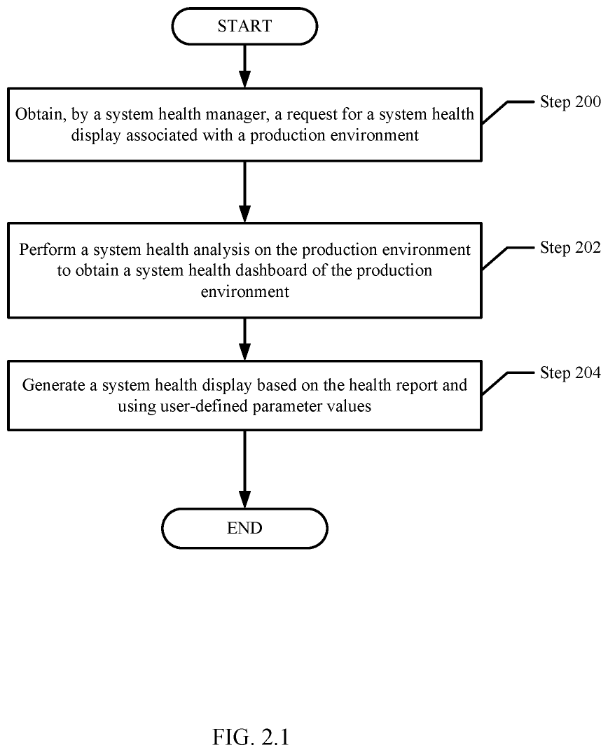

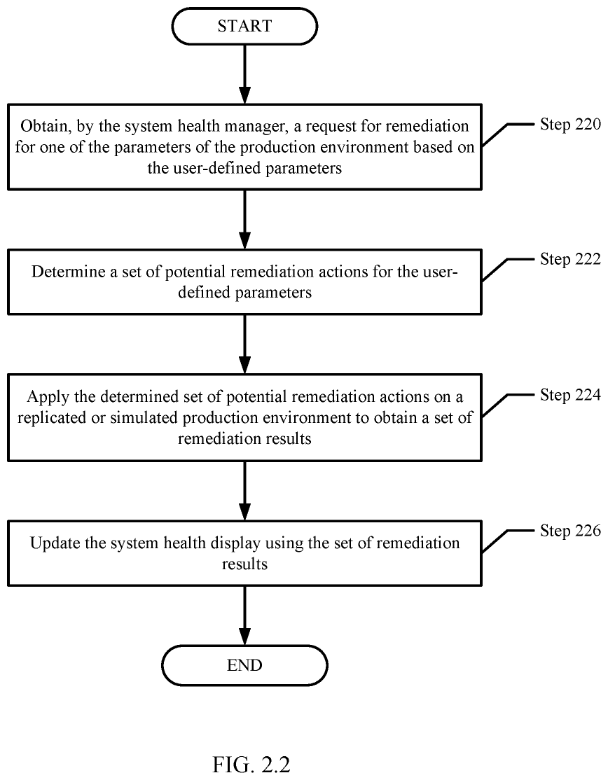

In one or more embodiments, the replicated or simulated production environments (154) (also referred to as simulated environments or replicated environments) are each a collection of resources used to mimic or otherwise imitate the resources of the production environment (130, FIG. 1.1) discussed above. Said another way, the simulated or replicated environments (154) may each include the resources that imitate the resources of the production host. The imitated resources may include the production hosts (132, 134, FIG. 1.1), the hardware resources, and/or the software resources of the production environment. The imitation of the production host by the simulated or replicated production environments (154) may provide evaluation services for the production host. For example, the system health manager (130) may use the replicated or simulated environments (154) to evaluate the effects of implementing any remediation actions (discussed in FIGS. 2.1-2.2) on the production environment. For example, a remediation action may be performed on a simulated environment to estimate the impact of the remediation actions on the parameters of the production environment. The results of the remediation actions (160) may be stored in the storage (156) and displayed in the system health display.

In one or more embodiments of the invention, the simulated or replicated environments (154) are implemented using any combination of physical or virtual devices that each imitate the resources of the production environment. For additional details regarding implementing the remediation actions on the simulated or replicated environments (154) to evaluate the impact on the production environment, refer to FIG. 2.2.

FIG. 2.1 shows a flowchart of a method of generating a system health display in accordance with one or more embodiments of the invention. The method shown in FIG. 2.1 may be performed by, for example, a system health manager (e.g., 150, FIG. 1.1). Other components of the system in FIG. 1.1 may perform all, or a portion, of the method of FIG. 2.1 without departing from the invention.

While FIG. 2.1 is illustrated as a series of steps, any of the steps may be omitted, performed in a different order, additional steps may be included, and/or any or all of the steps may be performed in a parallel and/or partially overlapping manner without departing from the invention.

Turning to FIG. 2.1, in step 200, a request for a system health display associated with a production environment is received. In one or more embodiments, the request specifies generating a display that illustrates the current system health of the production environment.

In step 202, a system health analysis is performed on the production environment to obtain a health dashboard of the production environment. In one or more embodiments, the system health analysis includes evaluating the resources of the production environment to analyze parameters of the production environment, such as the performance, latency, energy consumption, etc. The parameters may be evaluated by monitoring the resources during a pre-defined period of time. In one or more embodiments, the result of the analysis includes generating a system health dashboard that specifies the results of the evaluation of the resources. The system health dashboard may specify numerical values associated with each of the parameters as determined during the system health analysis.

In step 204, a system health display is generated based on the health dashboard and based on user-defined parameter values. In one or more embodiments, the system health display may specify the contents of the health dashboard and the numerical values associated with each of the parameters. Specifically, the system health display may specify a relationship between a current indicator of each parameter to the corresponding user-defined parameter values. For example, for a parameter of energy consumption, the system health display may illustrate the relationship between the current energy consumption rate of the production environment and the relative placement of this current parameter relative to expected SLA and SLO values. An example of this display may be found and further discussed in FIG. 3.3. The system health display may provide such relationships for one or more parameters as evaluated in the system health dashboard. Other information may be illustrated in the system health display without departing from the invention.

FIG. 2.2 shows a flowchart of a method of updating the system health display using a replicated or simulated environment in accordance with one or more embodiments of the invention. The method shown in FIG. 2.2 may be performed by, for example, the system health manager (e.g., 150, FIG. 1.1). Other components of the system in FIG. 1.1 may perform all, or a portion, of the method of FIG. 2.2 without departing from the invention.

While FIG. 2.2 is illustrated as a series of steps, any of the steps may be omitted, performed in a different order, additional steps may be included, and/or any or all of the steps may be performed in a parallel and/or partially overlapping manner without departing from the invention.

Turning to FIG. 2.2, in step 220, a request for remediation for one of the parameters is obtained. In one or more embodiments, the request for remediation specifies a parameter that does not meet the user-defined parameters such as the SLA. In such embodiments, the request for remediation specifies providing a set of remediation actions for remediating this parameter.

In step 222, a set of potential remediation actions are determined for the user-defined parameters. In one or more embodiments, the set of potential remediation actions are determined based on previously-implemented remediation on the production environment (or other production environments). Additionally, the set of potential remediation actions may be determined based on a catalogue of existing remediation actions that are each tagged based on their impact on the parameters and their impacts on the production environment. Examples of remediation actions that may be determined include, but are not limited to: reconfiguring the production environment according to a recommendation generated by the system health manager (or an information technology (IT) specialist of the production environment), increasing a number of hosts in the production environment, and resetting underperforming services of the production environment.

In step 224, the determined set of potential remediation actions are applied to a replicated or simulated production environment to obtain a set of remediation results. In one or more embodiments, the system health manager may initiate a simulation of the production environment based on the current configurations of the hardware and software of the production environment. Following the initiation of the simulation (or replication) the system health manager may apply one of the set of potential remediation actions on the simulated (or replicated) environment. The behavior of the simulated or replicated environment may be monitored to identify an impact of the potential remediation action. The remediation results may specify the behavior. The simulated (or replicated) environment may be reverted to the simulated state prior to implementing the remediation action. The process may be repeated for each of the set of remediation actions, and the remediation results may be updated based on the corresponding behavior of the simulated or replicated environments. In this manner, the system health manager may estimate the impact of each of the set of potential remediation actions on the parameters of the production environment.

In step 226, the system health display is updated using the set of remediation results. In one or more embodiments, the system health display is updated to indicate the set of remediation actions and the impact that each remediation action has on the current indicator of the corresponding parameter. For example, an impact of a first remediation action may be illustrated using an arrow whose length and direction corresponds to an amount that the remediation action may impact a parameter of the production host along a one dimensional axis representative of the domain of the parameter. An example of such arrows may be illustrated in FIGS. 3.1-3.4.

In one or more embodiments, the system health display may be updated by illustrating an estimated indicator of the parameter along the one dimensional axis and illustratively comparing the estimated indicator to a current indicator of the parameter. In this manner, a user viewing the system health display may visually compare the impact of the remediation action on a parameter (e.g., latency) when deciding whether to implement the remediation action.

In one or more embodiments, the user may use the system health display to select a remediation action (from the illustrated set of remediation actions) to implement on the production environment. After the selection and during the implementation of the remediation action, the current indicator of each parameter impacted by the remediation action may be updated and moved along the one dimensional axis. This movement may be toward the estimated indicator of the completed remediation action until, for example, the current indicator converges toward the estimated indicator.

To further clarify embodiments of the invention described throughout this disclosure, a non-limiting example is provided in FIGS. 3.1-3.4.

### Example

Consider a scenario in which a user of a client device has initiated a request for a system health display of a production environment in accordance with one or more embodiments of the invention. In this example, the production environment provides data processing services for a web-based video game. A system health manager performs the methods of FIGS. 2.1-2.2 to provide the system health display and possible remediation actions. Specifically, the system health display may, in response to the request for the display, perform a system health analysis on the production environment to obtain a system health dashboard. The system health dashboard specifies a current indicator of the performance, latency, and energy consumption parameters of the production environment. The information specified in the system health dashboard may be illustrated in the system health display.

Turning to FIG. 3.1, FIG. 3.1 shows a diagram of the system health display for the performance parameter. The system health display illustrated in FIG. 3.1 includes a current indicator (300) that illustrates the relationship of the performance of the production environment relative to user-defined parameter values (308, 310) of the performance along a one dimensional axis (312). The user-defined parameter values are illustrated in FIGS. 3.1-3.4 as “SLA” and “SLO”. The SLA performance indicator (308) represents a minimum defined performance parameter value of the performance that the production environment is expected to meet. The SLO performance indicator (310) represents a target or expected performance parameter value that the production environment should aim to meet. Along the axis (312), the performance values are higher on the right and lower in value toward the left. In this example, the current indicator (300) is to the right of and very near to the SLA indicator (308) and to the left of the SLO indicator (310), indicating the production environment is under-performing in this parameter and approaching a potential issue with meeting the SLA.

The user, viewing this indication of under-performance, initiates a request for remediation. The system health manager, in response to the request, determines a set of potential remediation actions that could be performed on the production environment to remediate the indicator performing below the SLA (308). The determined potential remediation actions are applied to a simulated environment that imitates the resources and performance of the production environment. Based on the results of performing the potential remediation actions on the simulated environment, the remediation results indicate that three potential remediation actions may resolve the issue. The three remediation actions are illustrated in FIGS. 3.1-3.4 as A1, A2, and A3. Remediation action Al relates to the action of reconfiguring the production environment based on a recommendation from an IT specialist; A2 relates to the action of increasing the number of hosts dedicated to the web-based video game; A3 relates to the action of re-setting under-performing services.

The impact of the remediation actions are illustrated in FIG. 3.1 as bold arrows (302, 304, 306). As illustrated in FIG. 3.1, the impact of implementing A1 (302) would have the greatest benefit on the performance parameter, the impact of implementing A2 (304) having the next best benefit, and the impact of A3 (306) having the lowest benefit. As illustrated in FIG. 3.1, all three impacts (302, 304, 306) would benefit the performance. Turning to FIG. 3.2, FIG. 3.2 shows a diagram of the system health display for the latency parameter. The system health display illustrated in FIG. 3.2 includes a current indicator (320) that illustrates the relationship of the latency of the production environment relative to user-defined parameter values (322, 324) of the performance along a second one dimensional axis (326). Similar to FIG. 3.1, the latency parameter is associated with corresponding SLA latency indicator (322) and SLO latency indicator (324), and the one dimensional axis (326) indicates more favorable values toward the right relative to the left. In this example, the latency indicator (320) is between the SLA latency indicator (322) and the SLO latency indicator (324), indicating that the latency is within the expected range, lower than the maximum user-defined latency, yet not as low as the preferred user-defined latency. Further, as illustrated in FIG. 3.2, none of the three remediation actions (i.e., A1, A2, A3) have any impact on the latency parameter.

Turning to FIG. 3.3, FIG. 3.3 shows a diagram of the system health display for the energy consumption parameter. The system health display illustrated in FIG. 3.3 includes a current indicator (330) that illustrates the relationship of the energy consumption of the production environment relative to user-defined parameter values (332, 334) of the energy consumption along a third one dimensional axis (338). Similar to FIG. 3.1, the energy consumption parameter is associated with corresponding SLA energy consumption indicator (332) and SLO energy consumption indicator (334), and the one dimensional axis (338) indicates more favorable values toward the right relative to the left. In this example, the energy consumption indicator (330) is between the SLA energy consumption indicator (332) and the SLO energy consumption indicator (334), indicating that the energy consumption is within the expected range, lower than the maximum user-defined energy consumption, yet not as low as the preferred user-defined energy consumption. Further, as illustrated in FIG. 3.3, only remediation action Al has any impact on the energy consumption parameter. Specifically, the impact of remediation action A1 (336) is estimated to negatively affect the energy consumption. The impact of A1 (336) would not bring the energy consumption to a worse value than the SLA (332).

In this example, the system health display enables the user to see the current state of all three parameters (i.e., performance, latency, and energy consumption) and the impacts of the remediation actions on each of the three parameters. The information displayed in the system health display may or may not display any numerical values. The one dimensional axes (312, 326, 338) may be standardized such that the right side of each axis (312, 326, 338) is more favorable relative to the left side. The user may, based on the information displayed in the system health display illustrated in FIGS. 3.1-3.3, select one of the three remediation actions (i.e., A1, A2, or A3) to implement to remediate the performance parameter. In this example, the user selects to implement remediation action A1.

Turning to FIG. 3.4, FIG. 3.4 shows a diagram of the system health display illustrating all three parameters and their corresponding indicators. FIG. 3.4 further illustrates an estimation indicator (342) for the performance parameter indicating an estimated state of the performance following implementation of remediation action A1. A second estimation indicator (344) for the energy consumption parameter is illustrated indicating an estimated state of the energy consumption following the implementation of A1. As the remediation action is being implemented on the production environment, the system health display illustrated in FIG. 3.4 is updated such that the current indicators (300, 320, 334) of the corresponding parameters move along their respective axes (312, 326, 338) to indicate the updated states of the corresponding parameters. As the remediation action is completed (as in, as the reconfiguration in accordance with the recommendation is applied), the current indicators (300, 320, 330) may move toward their respective estimation indicators (342, 344). In this example, this may result in the performance parameter current indicator (300), after completion of A1 on the production environment, the performance parameter may be within the user-defined parameters (308, 310).

### End of Example

As discussed above, embodiments of the invention may be implemented using computing devices. FIG. 4 shows a diagram of a computing device in accordance with one or more embodiments of the invention. The computing device (400) may include one or more computer processors (402), non-persistent storage (404) (e.g., volatile memory, such as random access memory (RAM), cache memory), persistent storage (406) (e.g., a hard disk, an optical drive such as a compact disk (CD) drive or digital versatile disk (DVD) drive, a flash memory, etc.), a communication interface (412) (e.g., Bluetooth interface, infrared interface, network interface, optical interface, etc.), input devices (410), output devices (408), and numerous other elements (not shown) and functionalities. Each of these components is described below.

In one embodiment of the invention, the computer processor(s) (402) may be an integrated circuit for processing instructions. For example, the computer processor(s) may be one or more cores or micro-cores of a processor. The computing device (400) may also include one or more input devices (410), such as a touchscreen, keyboard, mouse, microphone, touchpad, electronic pen, or any other type of input device. Further, the communication interface (412) may include an integrated circuit for connecting the computing device (400) to a network (not shown) (e.g., a local area network (LAN), a wide area network (WAN) such as the Internet, mobile network, or any other type of network) and/or to another device, such as another computing device.

In one embodiment of the invention, the computing device (400) may include one or more output devices (408), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (402), non-persistent storage (404), and persistent storage (406). Many different types of computing devices exist, and the aforementioned input and output device(s) may take other forms.

Embodiments of the invention may provide a system and method for managing and improving a production environment using displays of the system health of the production environment. The system health displays in accordance with one or more embodiments reduce the arbitrary numbering of any health scores that may be generated from health reports performed during the monitoring of the production environment. Instead, the system health displays in accordance with one or more embodiments of the invention may provide indicators of parameters of the production environment relative to user-defined values. In this manner, the displayed information may be relevant to the user in deciding how to remediate any under-performing parameters.

Embodiments disclosed herein include estimating the impacts of remediation actions by utilizing simulated environments that imitate the production host. The use of these simulated environments may provide estimates about the impact without directly affecting the production environment. The aforementioned system health displays may further illustrate these estimated impacts, enabling the user to select a most preferred remediation action.

Thus, embodiments of the invention may address the problem of limited computing resources in a distributed system. The problems discussed above should be understood as being examples of problems solved by embodiments of the invention of the invention and the invention should not be limited to solving the same/similar problems. The disclosed invention is broadly applicable to address a range of problems beyond those discussed herein.

One or more embodiments of the invention may be implemented using instructions executed by one or more processors of a computing device. Further, such instructions may correspond to computer readable instructions that are stored on one or more non-transitory computer readable mediums.

While the invention has been described above with respect to a limited number of embodiments, those skilled in the art, having the benefit of this disclosure, will appreciate that other embodiments can be devised which do not depart from the scope of the invention as of the invention. Accordingly, the scope of the invention should be limited only by the attached claims.

What is claimed is:

1. A method for managing system health of a production environment, the method comprising:
obtaining a request for remediation of a user-defined parameter of the production environment;
determining a set of potential remediation actions for the user-defined parameter;
applying each of the set of potential remediation actions to a simulated production environment to obtain a set of remediation results;
updating a system health display using the set of remediation results to obtain an updated system health display, wherein the updated system health display comprises a display of the user-defined parameter and an impact of a remediation action of the set of remediation actions on the user-defined parameter; and
implementing the remediation action of the set of remediation actions to service the request for remediation.

2. The method of claim 1, further comprising:
prior to obtaining the request for remediation:
obtaining, from a client device utilizing the production environment, a second request for the system health display associated with the production host environment;
performing a system health analysis on the production environment to obtain a system health dashboard of the production environment; and
generating the system health display based on the system health dashboard.

3. The method of claim 2, wherein a user of the client device defines a service level agreement (SLA) and service level objective (SLO) of the user-defined parameter.

4. The method of claim 1, wherein the updated system health display further comprises a display of an impact of the remediation action on a set of user-defined parameters, wherein the set of user-defined parameters comprise the user-defined parameter.

5. The method of claim 4, wherein the updated system health display further comprises an impact of a second remediation action on the set of user-defined parameters.

6. The method of claim 1, wherein the user-defined parameter comprises at least one of: a performance parameter, a latency parameter, and an energy conservation parameter.

7. The method of claim 1, wherein the set of remediation actions comprises at least one of: reconfiguring the production environment according to a recommendation, increasing a number of hosts in the production environment, and resetting underperforming services.

8. A non-transitory computer readable medium comprising computer readable program code, which when executed by a computer processor enables the computer processor to perform a method for managing system health of a production environment, the method comprising:
obtaining, from a client device, a request for remediation of a user-defined parameter of the production environment;
determining a set of potential remediation actions for the user-defined parameter;
applying each of the set of potential remediation actions to a simulated production environment to obtain a set of remediation results;
updating a system health display using the set of remediation results to obtain an updated system health display, wherein the updated system health display comprises a display of the user-defined parameter and an impact of a remediation action of the set of remediation actions on the user-defined parameter; and
implementing the remediation action of the set of remediation actions to service the request for remediation.

9. The non-transitory computer readable medium of claim 8, further comprising:
prior to obtaining the request for remediation:
obtaining, from a client device utilizing the production environment, a second request for the system health display associated with the production host environment;
performing a system health analysis on the production environment to obtain a system health dashboard of the production environment; and
generating the system health display based on the system health dashboard.

10. The non-transitory computer readable medium of claim 9, wherein a user of the client device defines a service level agreement (SLA) and service level objective (SLO) of the user-defined parameter.

11. The non-transitory computer readable medium of claim 8, wherein the updated system health display further comprises a display of an impact of the remediation action on a set of user-defined parameters, wherein the set of user-defined parameters comprise the user-defined parameter.

12. The non-transitory computer readable medium of claim 11, wherein the updated system health display further comprises an impact of a second remediation action on the set of user-defined parameters.

13. The non-transitory computer readable medium of claim 8, wherein the user-defined parameter comprises at least one of: a performance parameter, a latency parameter, and an energy conservation parameter.

14. The non-transitory computer readable medium of claim 8, wherein the set of remediation actions comprises at least one of: reconfiguring the production environment according to a recommendation, increasing a number of hosts in the production environment, and resetting underperforming services.

15. A system, comprising:
a processor; and
memory including instructions, which when executed by the processor, perform a method comprising:
obtaining, from a client device, a request for remediation of a user-defined parameter of the production environment;
determining a set of potential remediation actions for the user-defined parameter;
applying each of the set of potential remediation actions to a simulated production environment to obtain a set of remediation results;
updating a system health display using the set of remediation results to obtain an updated system health display, wherein the updated system health display comprises a display of the user-defined parameter and an impact of a remediation action of the set of remediation actions on the user-defined parameter; and
implementing the remediation action of the set of remediation actions to service the request for remediation.

16. The system of claim 15, further comprising:
prior to obtaining the request for remediation:
obtaining, from a client device utilizing the production environment, a second request for the system health display associated with the production host environment;
performing a system health analysis on the production environment to obtain a system health dashboard of the production environment; and
generating the system health display based on the system health dashboard.

17. The system of claim 16, wherein a user of the client device defines a service level agreement (SLA) and service level objective (SLO) of the user-defined parameter.

18. The system of claim 15, wherein the updated system health display further comprises a display of an impact of the remediation action on a set of user-defined parameters, wherein the set of user-defined parameters comprise the user-defined parameter.

19. The system of claim 18, wherein the updated system health display further comprises an impact of a second remediation action on the set of user-defined parameters.

20. The system of claim 15, wherein the set of remediation actions comprises at least one of: reconfiguring the production environment according to a recommendation, increasing a number of hosts in the production environment, and resetting underperforming services.
